(19) United States
(12) Patent Application Publication
(10) Pub. No.: US 2007/0205444 A1
(43) Pub. Date: Sep. 6, 2007

(54) Architecture of a n-type metal-oxide-semiconductor transistor with a compressive strained silicon-germanium channel fabricated on a silicon (110) substrate

(76) Inventors: Guangli Luo, Hsinchu (TW); Chao-Hsin Chien, Hsinchu (TW); Tsung-Hsi Yang, Tanzih Township (TW); Chun-Yen Chang, Hsinchu City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/431,697

(22) Filed: May 11, 2006

(30) Foreign Application Priority Data
Mar. 3, 2006 (TW) 95107229

(51) Int. Cl. H01L 29/76

(52) U.S. Cl. 257/288

(57) ABSTRACT

The present invention discloses an architecture of a NMOS transistor with a compressive strained Si—Ge channel fabricated on a silicon (110) substrate, which comprises: a p-silicon (110) substrate, two n⁺ ion-implanted regions functioning as the source and the drain respectively, a compressive strained Si—Ge channel layer, and a gate structure. The compressive strained Si—Ge channel layer is grown on the p-silicon (110) substrate to reduce the electron conductivity effective mass in the [1_l -10] crystallographic direction and to promote the electron mobility in the [1-10] crystallographic direction. Thus, the present invention can improve the electron mobility of a NMOS transistor via the channels fabricated on the silicon (110) substrate. Further, the NMOS transistor of the present invention can combine with a high-speed PMOS transistor on a silicon (110) substrate to form a high-performance CMOS transistor on the same silicon (110) substrate.

### BACKGROUND OF THE INVENTION

1. Field of the Invention

The present invention relates to an architecture of a NMOS transistor, particularly to an architecture of a NMOS transistor with a compressive strained Si—Ge channel on a p-silicon (110) substrate.

2. Description of the Related Art

For the current mainstream technology, the most widely used transistor is MOSFET, i.e. the metal-oxide-semiconductor field-effect transistor. Inside MOSFET, the current conduction is via the carrier movement along the channel closing to the interface. For a MOS transistor, if the current is conducted via electrons, it is called the n-type MOS (NMOS) transistor; if the current is conducted via electron holes, it is called the p-type MOS (PMOS) transistor. Herein, the NMOS transistor is used for exemplification. Refer to FIG. 1 a diagram schematically showing the structure of an NMOS transistor. The NMOS transistor 1 comprises: a p-type substrate 2, two n-type ion-implanted regions 3 and 4, which are embedded in the p-type substrate 2, an oxide layer 5, which is formed on the surface of the p-type substrate 2, a gate layer 6, which is formed on the oxide layer 5; and a spacer 7, which acts as a sidewall of the oxide layer 5 and the gate layer 6.

For recent years, the endeavors to promote the MOSFET via scaling-down technology has been bottlenecked by photolithographic problems, high fabrication cost, and device physical problems such as the gate current leakage and the short-channel effect. The mobility enhancement by strain, new materials such as Ge or SiGe channels, and new substrate orientation such as (110) and (111) can offer an alternative solution to the abovementioned problems. For example, many manufacturers adopt tensile strained silicon channel to promote the performances of n-type MOSFET, and compressive silicon channel to promote p-type MOSFET.

Very recently, the results of recent theoretical and experimental researches by an IBM research team point out that the hole mobility of the p-type MOSFET fabricated on the silicon (110) substrate is twice faster than that fabricated on the conventional (100) silicon substrate. Such a discovery can be used to solve the problem of low hole mobility for the PMOS transistor. However, this research team also point out that the electron mobility is reduced on the silicon (110) substrate. Thus, for a CMOS (complementary MOS) transistor, which has a NMOS transistor and a PMOS transistor simultaneously, the silicon (110) substrate will sacrifice the NMOSFET performance, albeit it can promote the PMOSFET performance. So the method of using silicon (110) substrate is still not optimal for improving the CMOS transistors.

Accordingly, the present invention proposes an architecture of a NMOS transistor with a compressive strained Si—Ge channel fabricated on a silicon (110) substrate to solve the problem of low electron mobility occurring inside the silicon (110) substrate.

### SUMMARY OF THE INVENTION

The primary objective of the present invention is to provide an architecture of a NMOS transistor with a compressive strained Si—Ge channel in p-silicon (110) substrate, and the compressive strained Si—Ge channel layer grown on a p-silicon (110) substrate is used to promote the electron mobility in the crystallographic direction [1-10].

Another objective of the present invention is to provide an architecture of a NMOS transistor with a strained Si—Ge channel in a p-silicon (110) substrate. To improve a CMOS transistor, the silicon (110) substrate is adopted to promote the hole mobility while the compressive strained Si—Ge channel is used to promote the electron mobility in the direction [1-10]. Thus, both kinds of the carriers can be conducted at high speed on the same silicon (110) substrate.

To achieve the abovementioned objectives, the present invention proposes an architecture of a NMOS transistor with a compressive strained Si—Ge channel fabricated on a p-silicon (110) substrate, wherein two n⁺ ion-implanted regions are embedded into the p-silicon (110) substrate to function as the source and the drain respectively, a strained Si—Ge channel layer is grown between those two ion-implanted regions, a gate structure is formed on the strained Si—Ge channel layer, a gate layer may be a polysilicon gate or a metallic gate, and the lateral side of the gate structure is covered with a sidewall. FIG. 2 is the schematic energy ellipsoids for compressive strained Si—Ge on the Si (110) substrate, wherein the dashed-line plane stands for the crystallographic plane (110). According to this architecture, under the compressive strain (due to the lattice mismatch between and Si—Ge Si), two Δ energy valleys in the [001] direction are lowered, and four Δ energy valleys in [100] and [010] directions are raised. With the increase of the compressively-strained degree inside the Si—Ge channel layer (It can be realized via increasing the Ge concentration), most of the electrons will move to two energy valleys in [001] direction. When electrons move along the [1-10] direction, the electron conductivity effective mass depends only on the effective mass in the direction of the short axis of the equi-energy ellipsoid, and the effective mass in this direction is the smallest. Therefore, the electron mobility can be promoted. Briefly to speak, the electrical performance of a NMOSFET element can be improved via growing strained Si—Ge film on a silicon (110) substrate and forming a channel along the [1-10] direction. Both the NMOS transistor of the present invention and the CMOS comprising a PMOS and the NMOS transistor of the present invention can have a higher carrier conduction speed.

To enable the objectives, technical contents, characteristics, and accomplishments of the present invention to be more easily understood, the preferred embodiments of the present invention are to be described in detail in cooperation with the attached drawings below.

### BRIEF DESCRIPTION OF THE DRAWINGS

FIG. 1 is a diagram schematically showing the structure of a conventional NMOS transistor.

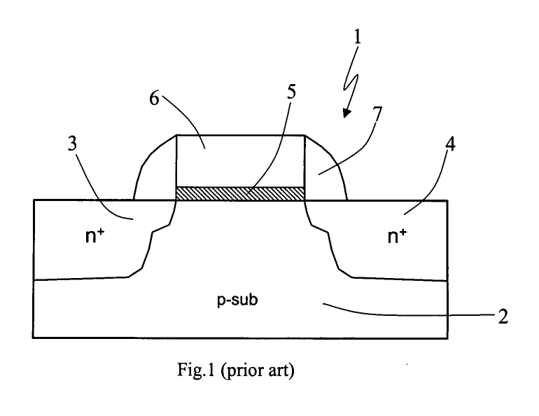

FIG. 2 is a diagram schematically showing the equi-energy ellipsoids of the compressive strained Si—Ge channel layer on the crystallographic plane (110) with the dashed-line rectangle denoting the crystallographic plane (110) according to the present invention.

FIG. 3 is a diagram schematically showing the structure of a polysilicon-gate NMOS transistor according to the present invention.

FIG. 4 is a diagram schematically showing the structure of a metallic-gate NMOS transistor according to the present invention.

FIG. 5 is a diagram schematically showing the structure of a CMOS transistor according to the present invention.

### DETAILED DESCRIPTION OF THE INVENTION

The MOS elements used in various electronic devices can be briefly divided into high-speed MOS elements and low-power-consumption MOS elements. At present, the strained-Si technology was employed to fabricate the MOSFETs, because an appropriate strain can enhance the carrier mobility in the Si channel. Further, different strains, such as a tensile strain and a compressive strain, have different influences on the mobilities of electrons and holes in different crystallographic directions on different crystallographic planes.

Several embodiments of the present invention will be described in detail below in order to prove the efficacy of the present invention, wherein a compressive strained Si—Ge channel layer is grown on the crystallographic plane (110) of a p-silicon substrate to promote the electron mobility of NMOS transistors.

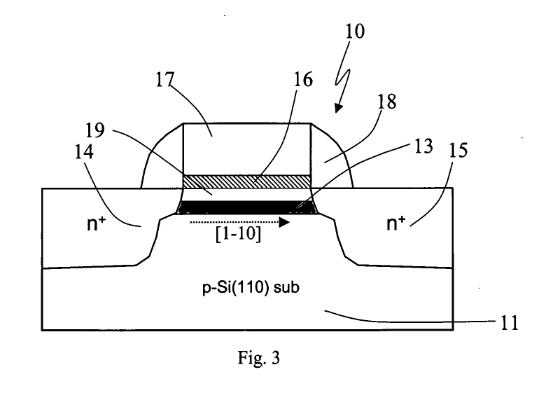

The present invention proposes an architecture of a NMOS transistor with a strained Si—Ge channel in p-silicon (110) substrate. An architecture of a polysilicon-gate NMOS transistor will be firstly used to exemplify the present invention. Refer to FIG. 3, a diagram schematically showing the structure of a polysilicon-gate NMOS transistor. A compressive strained Si—Ge channel layer 13 is first grown on a p-silicon (110) substrate 11 via an ultra-high vacuum/chemical vapor deposition method or a molecular beam epitaxy method. Next, a silicon cap layer 19 is formed on the compressive strained Si—Ge channel layer 13. Next, a gate oxide layer 16 is formed on the surface of the silicon cap layer 19, and the gate oxide layer 16 may be a silicon dioxide material. Next, a polysilicon gate layer 17 is formed on the gate oxide layer 16. Next, a spacer 18 is formed on the lateral side of the polysilicon gate layer 17 via a silicon oxide deposition technology and an etching process. Then, an ion implant technology is used to implant an appropriate amount of n-type dopant into the p-silicon (110) substrate 11 to form two ion-implanted regions 14 and 15, which function as the source and the drain respectively. The electron channel of the polysilicon-gate NMOS transistor 10 is formed along the [1-10] crystallographic direction (denoted by an arrow with a dotted line).

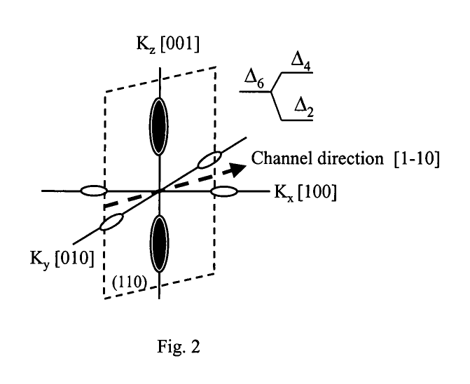

In the abovementioned polysilicon-gate NMOS transistor 10, the compressive strained Si—Ge channel layer 13 is formed on the p-silicon (110) substrate 11 with electrons conducted along the [1-10] crystallographic direction. Refer to FIG. 2 a diagram schematically showing the equi-energy ellipsoids of the Si—Ge channel layer on the crystallographic plane (110). The dashed-line plane is the (110) plane of the p-silicon (110) substrate 11. The arrow with a rough dashed line denotes the conduction direction of electrons in the compressive strained Si—Ge channel layer 13. As Si—Ge channel layer 13 is under the compressive strain on the p-silicon (110) substrate 11, the energy valley distributions in the Kx, Ky, and Kz directions are in the states of that two Δ energy valleys in the [001] direction are lowered and four A energy valleys respectively in [100] and [010] directions are raised. With the increase of the compressively-strained degree inside the Si—Ge channel layer (It can be realized via increasing the Ge concentration), most of the electrons will move to two lowered Δ energy valleys in [001] direction. When electrons move along the [1-10] direction in the crystallographic plane (110), the conductivity effective mass of electrons depends only on the effective mass in the direction of the short axis of the equi-energy ellipsoid. The effective mass in this direction is the smallest. Therefore, the electron mobility can be obviously increased, and the high-speed electrical performance of the polysilicon-gate NMOS transistor 10 can also be greatly promoted.

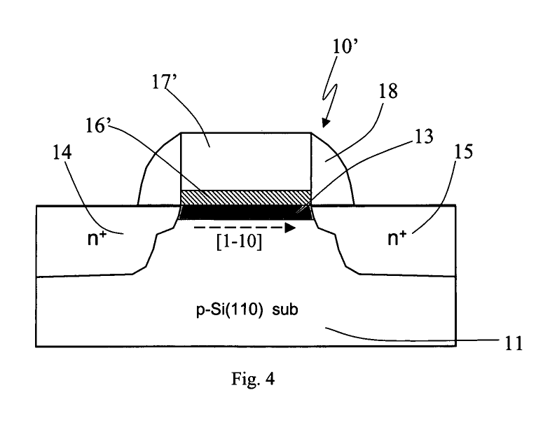

In the followings, an architecture of a metallic-gate NMOS transistor will be used to exemplify the present invention. Refer to FIG. 4 a diagram schematically showing the structure of a metallic-gate NMOS transistor. A compressive strained Si—Ge channel layer 13 is first grown on a p-silicon (110) substrate 11 via an ultra-high vacuum/chemical vapor deposition method or a molecular beam epitaxy method. Next, a gate insulation layer 16′ is formed on the compressive strained Si—Ge channel layer 13, and the gate insulation layer 16′ may be made of a high-permittivity (high-k) material. Next, a metallic gate layer 17′ is formed on the gate insulation layer 16′. Next, a spacer 18 is formed on the lateral side of the gate insulation layer 16′ and the metallic gate layer 17′. Then, an ion implant technology is use to implant an appropriate amount of n-type dopant into the p-silicon (110) substrate 11 to form two ion-implanted regions 14 and 15, which function as the source and the drain separately. The electron channel of the metallic-gate NMOS transistor 10′ is formed along the [1-10] crystallographic direction (denoted by an arrow with a dotted line).

Similar to the embodiment of the polysilicon-gate NMOS transistor 10, in the abovementioned metallic-gate NMOS transistor 10′, the strained Si—Ge channel layer 13 is also formed on the p-silicon (110) substrate 11 with electrons conducted along the [1-10] crystallographic direction. The compressive stain inside the Si—Ge channel layer 13 greatly reduces the effective mass of carriers in the [1-10] crystallographic direction. Thus, the electron mobility is obviously increased so that the metallic-gate NMOS transistor 10′ has a superior high-speed electric performance.

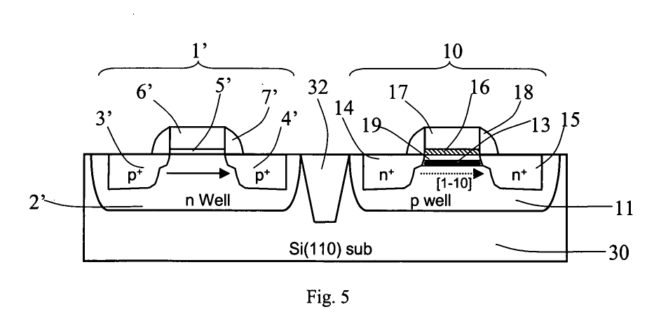

Further, the application of the architecture of an NMOS transistor of the present invention to CMOSFET transistor is to be used to exemplify the present invention below. Refer to FIG. 5 a diagram schematically showing the structure of a CMOSFET transistor. A PMOS transistor 1′ and either of the abovementioned two NMOS transistors of the present invention are embedded into a p-silicon (110) substrate 30. And also, the PMOS transistor 1′ and either of the abovementioned two NMOS transistors of the present invention are separated by a STI structure 32. The PMOS transistor 1′ may be any PMOS transistor and is formed via: providing an n-well 2′, embedding two p-type ion-implanted regions 3′ and 4′ into the n-well 2′, forming an oxide layer 5′ on the surface of the n-well substrate 2′, forming a gate layer 6′ on the oxide layer 5′, and forming a spacer 7′ on the lateral side of the oxide layer 5′ and the gate layer 6′. In FIG. 5, the polysilicon-gate NMOS transistor 10 shown in FIG. 3 is adopted to exemplify the NMOS transistor. The structure of the polysilicon-gate NMOS transistor 10 is the same as that disclosed above and will not be described again here. Besides, the metallic-gate NMOS transistor 10′ shown in FIG. 4 may also be adopted as the NMOS transistor in FIG. 5. In the CMOSFET transistor adopting the NMOS transistor of the present invention, the electron mobility in the [1-10] crystallographic direction (denoted by an arrow with a solid line and an arrow with a dotted line) is also increased due to the NMOS transistor of the present invention. Thus, the CMOSFET transistor can also have a superior high-speed electric performance.

In summary, the present invention clearly discloses an architecture of an NMOS transistor with a compressive strained Si—Ge channel in a silicon (110) substrate, which can reduce the electron conductivity effective mass along the [1-10] crystallographic direction in the crystallographic plane (110), thereby promote the mobility of carriers, and solve the problem of low electron mobility in the silicon (110) substrate. An important application of the NMOS transistor of the present invention is to combine with a PMOS transistor fabricated on a silicon (110) substrate to form various high carrier mobility CMOSFET transistors to meet the requirements of various final products.

Those embodiments described above are to clarify the present invention to enable the persons skilled in the art to understand, make and use the present invention; however, it is not intended to limit the scope of the present invention, and any equivalent modification and variation according to the spirit of the present invention is to be also included within the scope of the claims stated below.

What is claimed is:

1. An architecture of an n-type metal-oxide-semiconductor transistor with a compressive strained silicon-germanium channel fabricated on a silicon (110) substrate, comprising:
a p-silicon (110) substrate;
two ion-implanted regions, embedded in the p-silicon (110) substrate;
a strained silicon-germanium channel layer, grown on the p-silicon (110) substrate, and located between the two ion-implanted regions; and
a gate structure, fabricated on the strained silicon-germanium channel layer.

2. The architecture of an n-type metal-oxide-semiconductor transistor with a compressive strained silicon-germanium channel fabricated on a silicon (110) substrate according to claim 1, wherein a P-type dopant is doped into the P-silicon substrate (110).

3. The architecture of an n-type metal-oxide-semiconductor transistor with a compressive strained silicon-germanium channel fabricated on a silicon (110) substrate according to claim 1, wherein the channel direction of the strained silicon-germanium channel layer is along the [1-10] crystallographic direction.

4. The architecture of an n-type metal-oxide-semiconductor transistor with a compressive strained silicon-germanium channel fabricated on a silicon (110) substrate according to claim 1, wherein the strained silicon-germanium channel layer is grown via an ultra-high vacuum/chemical vapor deposition method or a molecular beam epitaxy method.

5. The architecture of an n-type metal-oxide-semiconductor transistor with a compressive strained silicon-germanium channel fabricated on a silicon (110) substrate according to claim 1, wherein the strained silicon-germanium channel layer can also be a compressive strained silicon layer.

6. The architecture of an n-type metal-oxide-semiconductor transistor with a compressive strained silicon-germanium channel fabricated on a silicon (110) substrate according to claim 1, wherein the ion-implanted regions respectively function as the n⁺ source and the n⁺ drain.

7. The architecture of an n-type metal-oxide-semiconductor transistor with a compressive strained silicon-germanium channel fabricated on a silicon (110) substrate according to claim 1, wherein the gate structure is a polysilicon gate structure.

8. The architecture of an n-type metal-oxide-semiconductor transistor with a compressive strained silicon-germanium channel fabricated on a silicon (110) substrate according to claim 7, wherein the polysilicon gate structure further comprises:
a silicon cap layer, grown on the strained silicon-germanium channel layer;
a gate oxide layer, formed on the silicon cap layer; and a polysilicon gate layer, formed on the gate oxide layer with spacer fabricated on sidewalls of the polysilicon gate layer and the gate oxide layer.

9. The architecture of an n-type metal-oxide-semiconductor transistor with a compressive strained silicon-germanium channel fabricated on a silicon (110) substrate according to claim 8, wherein the gate oxide layer is made of silicon dioxide.

10. The architecture of an n-type metal-oxide-semiconductor transistor with a compressive strained silicon-germanium channel fabricated on a silicon (110) substrate according to claim 1, wherein the gate structure is a metallic gate structure.

11. The architecture of an n-type metal-oxide-semiconductor transistor with a compressive strained silicon-germanium channel fabricated on a silicon (110) substrate according to claim 10, wherein the metallic gate structure further comprises:
a gate insulation layer, formed on the strained silicon-germanium channel layer; and a metallic gate layer, formed on the gate insulation layer with spacer fabricated on sidewalls of the metallic gate layer and the gate insulation layer.

12. The architecture of an n-type metal-oxide-semiconductor transistor with a compressive strained silicon-germanium channel fabricated on a silicon (110) substrate according to claim 11, wherein the gate insulation layer is made of a high-permittivity (high-k) material.

13. An architecture of a complementary metal-oxide-semiconductor transistor with a compressive strained silicon-germanium channel fabricated on a silicon (110) substrate, comprising:
a silicon (110) substrate;
a p-type metal-oxide-semiconductor transistor, formed on the silicon (110) substrate; and
an n-type metal-oxide-semiconductor transistor, formed on the silicon (110) substrate, neighboring and connecting the p-type metal-oxide-semiconductor transistor, and further comprising:
a p-type well formed inside the silicon (110) substrate;
two ion-implanted regions, embedded in the p-type well;
a strained silicon-germanium channel layer, formed in the p-type well, and located between the two n⁺ ion-implanted regions; and
a gate structure, fabricated on the strained silicon-germanium channel layer.

14. The architecture of a complementary metal-oxide-semiconductor transistor with a compressive strained silicon-germanium channel fabricated on a silicon (110) substrate according to claim 13, wherein the semiconductor substrate is a p-type silicon substrate or an n-type silicon substrate.

15. The architecture of a complementary metal-oxide-semiconductor transistor with a compressive strained silicon-germanium channel fabricated on a silicon (110) substrate according to claim 13, wherein the p-type metal-oxide-semiconductor transistor is fabricated in an n-type well, and the n-type well is formed inside the silicon (110) substrate.

16. The architecture of a complementary metal-oxide-semiconductor transistor with a compressive strained silicon-germanium channel fabricated on a silicon (110) substrate according to claim 13, wherein the P-type silicon substrate (110) is doped with P-type ions to form two p⁺ ion-implanted regions, which are respectively function as a source and a drain.

17. The architecture of a complementary metal-oxide-semiconductor transistor with a compressive strained silicon-germanium channel fabricated on a silicon (110) substrate according to claim 13, wherein the channel direction of the strained silicon-germanium channel layer in the n-type metal-oxide-semiconductor transistor is along the [1-10] crystallographic direction.

18. The architecture of a complementary metal-oxide-semiconductor transistor with a compressive strained silicon-germanium channel fabricated on a silicon (110) substrate according to claim 13, wherein the strained silicon-germanium channel layer is formed via an ultra-high vacuum/chemical vapor deposition method or a molecular beam epitaxy method.

19. The architecture of a complementary metal-oxide-semiconductor transistor with a compressive strained silicon-germanium channel fabricated on a silicon (110) substrate according to claim 13, wherein the strained silicon-germanium channel layer can also be a compressive strained silicon layer.

20. The architecture of a complementary metal-oxide-semiconductor transistor with a compressive strained silicon-germanium channel fabricated on a silicon (110) substrate according to claim 13, wherein the gate structure is a polysilicon gate structure.

21. The architecture of a complementary metal-oxide-semiconductor transistor with a compressive strained silicon-germanium channel fabricated on a silicon (110) substrate according to claim 19, wherein the polysilicon gate structure further comprises:
a silicon cap layer grown on the strained silicon-germanium channel layer;
a gate oxide layer, formed on the silicon cap layer; and
a polysilicon gate layer, formed on the gate oxide layer with a spacer fabricated on sidewalls of the polysilicon gate layer and the gate oxide layer.

22. The architecture of a complementary metal-oxide-semiconductor transistor with a compressive strained silicon-germanium channel fabricated on a silicon (110) substrate according to claim 20, wherein the gate oxide layer is made of silicon dioxide.

23. The architecture of a complementary metal-oxide-semiconductor transistor with a compressive strained silicon-germanium channel fabricated on a silicon (110) substrate according to claim 13, wherein the gate structure is a metallic gate structure.

24. The architecture of a complementary metal-oxide-semiconductor transistor with a compressive strained silicon-germanium channel fabricated on a silicon (110) substrate according to claim 22, wherein the metallic gate structure further comprises:
a gate insulation layer, formed on the surface of the p-type silicon (110) substrate, and covering the strained silicon-germanium channel layer; and
a metallic gate layer, formed on the gate insulation layer with a spacer fabricated on sidewalls of the metallic gate layer and the gate insulation layer.

25. The architecture of a complementary metal-oxide-semiconductor transistor with a compressive strained silicon-germanium channel fabricated on a silicon (110) substrate according to claim 23, wherein the gate insulation layer is made of a high-permittivity (high-k) material.
